(19) United States
(12) Patent Application Publication
(10) Pub. No.: US 2016/0172327 A1
(43) Pub. Date: Jun. 16, 2016

(54) Low-Temperature Bonding and Sealing With Spaced Nanorods

(71) Applicant: UNIVERSITY OF CONNECTICUT, Farmington, CT (US)

(72) Inventors: Stephen P. Stagon, Jacksonville, FL (US); Hanchen Huang, Newton, MA (US)

(73) Assignee: University of Connecticut, Farmington, CT (US)

(21) Appl. No.: 14/899,868

(22) PCT Filed: Jun. 19, 2014
(86) PCT No.: PCT/US2014/043139

§ 371 Date: Dec. 18, 2015

Related U.S. Application Data
(60) Provisional application No. 61/837,814, filed on Jun. 21, 2013.

(51) Int. Cl. H01L 23/00; H01L 51/52; H01L 51/56; H01L 51/44

(52) U.S. Cl. CPC H01L 24/83; H01L 24/27; H01L 51/448; H01L 51/5246; H01L 51/56; H01L 24/32; H01L 2924/12041; H01L 2924/12043; H01L 2924/12044; H01L 2924/1207; H01L 2924/14; H01L 2924/1421; H01L 2224/29144; H01L 2224/29139; H01L 2224/29111; H01L 2224/29116; H01L 2224/29109; H01L 2224/29147; H01L 2224/29124; H01L 2224/2745; H01L 2224/27452; H01L 2924/01014; H01L 2924/20105; H01L 2924/20104; H01L 2924/20103; H01L 2924/20102; H01L 2224/83203; H01L 2224/32225; H01L 2224/32501; H01L 2224/83099; H01L 2224/83193

(57) ABSTRACT

The present disclosure provides improved systems and methods for low-temperature bonding and/or sealing with spaced nanorods. In exemplary embodiments, the present disclosure provides for the use of metallic nanorods to bond and seal two substrates. The properties of the resulting bond are mechanical strength comparable to adhesives, impermeability comparable to metals and long term stability comparable to metals. The bond may be attached to any flat substrate and superstate with strong adhesion. In certain embodiments, the bond is achieved at room temperature with only pressure or at a temperature above room temperature (e.g., about 150° C. or less) and reduced pressure. Exemplary bonds are both mechanically strong and substantially impermeable to oxygen and moisture.

### CROSS-REFERENCE TO RELATED APPLICATIONS

This application claims the benefit of U.S. Provisional Application No. 61/837,814 filed Jun. 21, 2013, all of which is herein incorporated by reference in its entirety.

### RELATED FEDERALLY SPONSORED RESEARCH

The work described in this patent disclosure was sponsored by the following Federal Agencies: DOE, Grant No. DE-FG02-09ER46562.

### BACKGROUND

1. Technical Field

The present disclosure relates to systems and methods for low-temperature bonding and/or sealing with spaced nanorods.

2. Background Art

In general, some conventional current systems and methods for bonding or sealing are application specific. For example and for the case of flexible electronics, organic solar cells and organic light emitting diodes, polymer adhesives, swage, or solder is conventionally being used for sealing. The polymer adhesives generally cannot meet the need for oxygen and moisture impermeability of many applications or devices. Further, even if the initial permeability of the polymer is sufficient, over time the polymer will typically degrade and the leak rate will become too high. Also, the use of low temperature solder typically causes the heating of the organic semiconductor past its glass transition temperature and decreases its performance and lifetime.

Thus, an interest exists for advantageous systems and methods for low-temperature bonding and/or sealing with spaced nanorods. These and other inefficiencies and opportunities for improvement are addressed and/or overcome by the assemblies, systems and methods of the present disclosure.

### SUMMARY

The present disclosure provides advantageous systems and methods for low-temperature bonding and/or sealing with spaced nanorods. The systems and methods of the present disclosure allow for room temperature (e.g., 18-24° C.) metallic bonding in an ambient environment at pressures well below the yield of common engineering materials. This is the first time this has ever been done.

In exemplary embodiments, the resulting bond is both mechanically strong and substantially impermeable to oxygen and moisture Importantly, this level of impermeability is found in an easily implementable platform for the first time. For example and without limitation, these characteristics make the bond ideal for organic light emitting diode (OLED) and organic photovoltaic (OPV) technologies. It is the first available technology that promises to meet the lifetime metrics for blocking oxygen and moisture through to the organic contents, but also is compatible with roll-to-roll (R2R) processing at a reasonable cost of materials and/or infrastructure.

In general, the systems and method of the present disclosure use a novel structure, well separated metallic nanorods, to bond together two or more pieces of material. In exemplary embodiments, since the bond is metal, it has mechanical strength comparable, or greater than, polymer adhesives, limited only by the strength of the adhesion to the substrate, and has superior long term stability in harsh conditions and superior resistance to the permeation of oxygen and moisture compared to polymer adhesives. The two sides are joined through fast diffusion on the nanorod surfaces and inter-digitation that is made possible by the well separated nature.

In exemplary embodiments, the present disclosure provides for the use of metallic nanorods to bond and seal two substrates. The properties of the resulting bond are mechanical strength comparable to adhesives, impermeability comparable to metals and long term stability comparable to metals. The bond may be attached to any flat substrate and superstrate with strong adhesion. In certain embodiments, the bond is achieved at room temperature (e.g., 18-24° C.) with only pressure or at a temperature above room temperature and reduced pressure.

The present disclosure provides for a method for bonding or sealing substrates including: a) providing a first substrate and a second substrate; b) depositing a first array of nanorods on the first substrate; c) depositing a second array of nanorods on the second substrate; d) aligning the first substrate over the second substrate, the first and second arrays of nanorods positioned and having adequate spacing between one another to allow for the interpenetration and inter-digitation of the first and second arrays when pressed together; and e) pressing the first substrate and the second substrate together to interpenetrate, interdigitate, and bond the first and second arrays of nanorods to one another.

The present disclosure also provides for a method for bonding or sealing substrates wherein the first and second substrates are selected from the group consisting of glass, metal, non-metal, silicon, plastic, flexible electronic, organic semiconductor, photovoltaic, LED, resistor, RFID tag, integrated circuit, LCD, solar cell, food or medication vacuum sealing substrates.

The present disclosure also provides for a method for bonding or sealing substrates wherein the first and second arrays of nanorods are selected from the group consisting of metallic, non-metallic, alloy, Au, Ag, Sn, Pb, In, Al, Cu, Sn, metal oxide nanorods, and nanorods having a metal core coated with a metal shell.

The present disclosure also provides for a method for bonding or sealing substrates wherein the first and second arrays of nanorods are deposited via physical vapor deposition, chemical deposition, physical deposition, or coating.

The present disclosure also provides for a method for bonding or sealing substrates wherein the pressing step in step e) occurs at a temperature of 150° C. or less. The present disclosure also provides for a method for bonding or sealing substrates wherein the pressing step in step e) occurs at a temperature of 100° C. or less. The present disclosure also provides for a method for bonding or sealing substrates wherein the pressing step in step e) occurs at a temperature of 75° C. or less. The present disclosure also provides for a method for bonding or sealing substrates wherein the pressing step in step e) occurs at ambient temperature.

The present disclosure also provides for a method for bonding or sealing substrates wherein the pressing step in step e) occurs at a pressure from about 1 MPa to about 20 MPa. The present disclosure also provides for a method for bonding or sealing substrates wherein the pressing step in step e) occurs at a pressure from about 1 MPa to about 5 MPa.

The present disclosure also provides for a method for bonding or sealing substrates wherein the bond is substantially impermeable to oxygen and moisture. The present disclosure also provides for a method for bonding or sealing substrates wherein the bond has a shear strength greater than about 10 MPa. The present disclosure also provides for a method for bonding or sealing substrates wherein the pressing step in step e) occurs via a heated or unheated die that applies pressure to the first and second substrates.

The present disclosure also provides for a method for bonding or sealing substrates wherein each nanorod in the first and second arrays of nanorods is about 20 nm in diameter. The present disclosure also provides for a method for bonding or sealing substrates wherein each nanorod in the first and second arrays of nanorods is about 10 nm in diameter.

The present disclosure also provides for a method for bonding or sealing substrates wherein first and second arrays of nanorods are deposited via a high vacuum electron beam physical vapor deposition system.

The present disclosure also provides for a method for depositing nanorods including: providing source material in a base of a chamber of a physical vapor deposition system; positioning a substrate in the chamber at an angle of about 85° or greater relative to the base of the chamber; and depositing the source material onto the substrate via the physical vapor deposition system to form nanorods on the substrate.

The present disclosure also provides for a method for depositing nanorods wherein the substrate is at a temperature of from about 4 K to about 24° C. during the deposition of the source material. The present disclosure also provides for a method for depositing nanorods wherein the substrate is at a temperature of about 250 K during the deposition of the source material. The present disclosure also provides for a method for depositing nanorods wherein the substrate includes heterogeneous nucleation sites. The present disclosure also provides for a method for depositing nanorods wherein the substrate is a non-wetting substrate.

The present disclosure also provides for a method for depositing nanorods wherein the source material is deposited at a rate of from about 0.1 nm/s to about 0.3 nm/s.

The present disclosure also provides for a method for depositing nanorods wherein each formed nanorod is about 20 nm in diameter. The present disclosure also provides for a method for depositing nanorods wherein each formed nanorod is about 10 nm in diameter.

The present disclosure also provides for a sealed substrate including a first substrate aligned over and bonded to a second substrate, the first and second substrates each having a plurality of nanorods deposited thereon, the plurality of nanorods positioned and having adequate spacing between one another to allow for the interpenetration and inter-digitation of the plurality of nanorods when pressed and bonded together. The present disclosure also provides for a sealed substrate wherein the plurality of nanorods include nanorods having a metal core coated with a metal shell.

Any combination or permutation of embodiments is envisioned. Additional advantageous features, functions and applications of the disclosed assemblies, systems and methods of the present disclosure will be apparent from the description which follows, particularly when read in conjunction with the appended figures. References, publications and patents listed in this disclosure are hereby incorporated by reference in their entireties.

### BRIEF DESCRIPTION OF THE DRAWINGS

Features and aspects of embodiments are described below with reference to the accompanying drawings, in which elements are not necessarily depicted to scale.

Exemplary embodiments of the present disclosure are further described with reference to the appended figures. It is to be noted that the various steps, features and combinations of steps/features described below and illustrated in the figures can be arranged and organized differently to result in embodiments which are still within the spirit and scope of the present disclosure. To assist those of ordinary skill in the art in making and using the disclosed systems, assemblies and methods, reference is made to the appended figures, wherein:

FIG. 1 shows a bond schematic and possible implementation in a solar cell or light emitting diode. The bottom figure (FIG. 1B) is the implementation in an organic solar cell. Top left image of FIG. 1A is a schematic of two adjacent substrates with metal layer and sparse/well separated nanorod array. Middle image of FIG. 1A is when the two layers are pressed together to have inter-penetration, and then heating may or may not be added to get a continuous bond, top right image of FIG. 1A;

FIG. 2 shows nanorod temperature progression: (a) As fabricated nanorod array with cross section as inset, (b) heated to 50° C. for 1 hr, (c) heated to 75° C. for 1 hr and (d) heated to 100° C. for 5 minutes.;

FIG. 3 displays a bond quality demonstration: (a) Cross sectional image of as fabricated nanorods on bond stack structure, (b) FIB prepared cross-section of 20 MPa and room temperature for 5 minutes, and (c) FIB cross section of 20 MPa and 75° C. for 1 hr and (d) FIB cross section of 20 MPa and 150° C. for 1 hr;

FIG. 4 depicts schematics of: (a) metallic bonding processes using nanorods, and (b) metallic versus polymer sealing of organic solar cells;

FIG. 5 depicts SEM images of Ag nanorods: (a) before annealing from a tilted top view, with the titled cross-section view as inset, (b) after annealing at 50° C. for 60 mins, (c) after annealing at 75° C. for 60 mins, and (d) after annealing at 100° C. for 60 minutes;

FIG. 6 depicts SEM images of bond cross sections under mechanical compression: (a) at room temperature for less than one minute, (b) at 75° C. for 60 mins, and (3) at room temperature for 60 minutes;

FIG. 7A shows that the pressure in a vacuum increases when the seal is completely plastic, and this rate is reduced when the seal is the metallic bond of FIG. 6B;

FIG. 7B shows that the bond of FIG. 6B does not break before either the plastic substrate fractures (left image of FIG. 7B) or delamination occurs between the bond and the substrate (right image of FIG. 7B);

FIG. 8 shows: (a) schematic of the two modes of nanorod growth, with mode II giving rise to the smallest nanorods; and (b) evolution of a nanorod, corresponding to the boxed one in (a), as a function of time for mode II;

FIG. 9 shows: (a) The theoretical distribution Sₙ(L) for various numbers of layers n in height; the inset shows a comparison of the numerical solution, the closed-form expression, and LKMC simulation results under complete geometrical shadowing as a function of (ν_{3D}/F)^{1/5}. (b) LKMC simulation results under incomplete geometry shadowing as a function of (ν_{3D}/F)^{1/5}; the separation of nanorod nuclei Lₛ is included for comparison, and the incidence angle is 85°. The inset shows nanorods from a LKMC simulation with random nucleation. (c) LKMC simulation results under incomplete geometry shadowing as a function of incidence angle, with either the same Fₑ=1 sin 5° nm/s or the same F=1 nm/s; the separation of nanorod nuclei Lₛ is included for comparison;

FIG. 10 shows scanning electron microscopy images of well-separated: (a) Cu and (b) Au nanorods at an early stage; the insets with the same scale show the morphologies of substrates;

FIG. 11 shows scanning electron microscopy images of: (a) Cu and (b) Au nanorods at a later stage when nanorods are about 1000 nm long; the insets with the same scale show surface morphologies of nanorods when conventional substrates are used; and

FIGS. 12A-C show SEM images of: (FIG. 12A) Cu nanorods coated with Sn, (FIG. 12B) Cu—Sn nanorods after mechanical pressure of about 5 MPa, and (FIG. 12C) film from heating Cu—Sn nanorods at about 100° C. under the pressure for about 5 minutes; insets are cross-sectional views.

### DETAILED DESCRIPTION

The exemplary embodiments disclosed herein are illustrative of advantageous methods for low-temperature bonding and/or sealing with spaced nanorods, and systems of the present disclosure and methods/techniques thereof. It should be understood, however, that the disclosed embodiments are merely exemplary of the present disclosure, which may be embodied in various forms. Therefore, details disclosed herein with reference to exemplary systems/methods and associated processes/techniques of assembly and use are not to be interpreted as limiting, but merely as the basis for teaching one skilled in the art how to make and use the advantageous systems/methods of the present disclosure.

The present disclosure provides improved systems and methods for low-temperature bonding and/or sealing with spaced nanorods. In exemplary embodiments, the systems and methods of the present disclosure allows for room temperature (e.g., 18-24° C.) metallic bonding in an ambient environment at pressures well below the yield of common engineering materials. This is the first time this has ever been done.

The resulting bond is both mechanically strong (e.g., shear strength is greater than about 10 MPa, comparable to cyanoacrylate) and substantially impermeable to oxygen and moisture (e.g., preliminary leak rate testing is indistinguishable from knife-edge vacuum gaskets and outperforms polymer by at least 1×10⁻⁵ g/m²/day of air) Importantly, this level of impermeability is found in an easily implementable platform for the first time. For example and without limitation, these characteristics make the bond ideal for organic light emitting diode (OLED) and organic photovoltaic (OPV) technologies. It is the first available technology that promises to meet the lifetime metrics for blocking oxygen and moisture through to the organic contents, but also is compatible with roll-to-roll (R2R) processing at a reasonable cost of materials and/or infrastructure.

In general, the systems and method of the present disclosure use a novel structure, well separated metallic nanorods, to bond together two or more pieces of material. In exemplary embodiments, since the bond is metal, it has mechanical strength comparable, or greater than, polymer adhesives, limited only by the strength of the adhesion to the substrate, and has superior long term stability in harsh conditions (e.g., elevated temperature, corrosive or oxidative environment, etc.) and superior resistance to the permeation of oxygen and moisture compared to polymer adhesives. The two sides are joined through fast diffusion on the nanorod surfaces and inter-digitation that is made possible by the well separated nature.

The bond consists of an adhesion layer, when necessary, for the metallization of nearly any flat (+/− several hundred nm) surface, an intermediate metallic bond layer for mechanical strength and to increase the total cross-sectional area of the bond to be tolerant to contamination, and a top “active” bond layer of metal or alloy nanorods which are well spaced to allow for the interpenetration of the rods from the top bond stack to those of the bottom bond stack. When applicable, either the adhesion layer or the intermediate bond layer may be eliminated. The two substrates, or the substrate (bottom) and superstrate (top), are placed in contact with one another with bond sides touching and mechanical pressure and/or heat or either only mechanical pressure or only heat is applied to the bond area.

In exemplary embodiments, the systems/methods of the present disclosure can be used in either a conductive configuration, all layers are metal, or an insulating configuration, an insulating layer is added at some point in the stack using physical vapor deposition (PVD).

In applications where low permeability to oxygen and moisture are important, a desiccant layer or component (e.g., nano or micro consisting of a thin film, nanoparticles, micro particles, etc.) may be physically or chemically deposited into the stack at any point to further reduce the permeability, or the stack may be partially masked to allow for only a small percentage of the area of the bond to have a desiccant layer or component.

For example and without limitation, exemplary end users of the systems and methods of the present disclosure may be in the areas of flexible electronics, organic semiconductors (e.g., photovoltaics, light emitting diodes or LEDs, resistors), radio-frequency identification (RFID) tags, integrated circuits and food or medication vacuum sealing. As further examples, the exemplary systems/methods can be used to seal or connect components for any, all, or a combination of the following: electrical conductivity, mechanical adhesion or joining, and/or impermeable sealing or the like. For example, two substrates can be joined together for an organic LED, solar cell, RFID tag or flexible electronics at a temperature that does not damage the internals and the seal will offer impermeability to oxygen and moisture and mechanical adhesion between the substrate and superstrate. Alternatively, interconnections or integrated circuit (IC) components may be treated so that the contacts are coated with the conductive active layers and pressure or heat is used to connect it to the other components.

In certain embodiments, the application will take place within a vacuum chamber or environmental chamber, and a physical vapor deposition will lay down the three, or more, layers, with or without desiccant, and may be done on R2R or separate substrates. The underlayers may also be applied via a chemical process. The two sides may then be placed together with active layers facing one another, either two rolls or two substrates, and a heated or unheated die may be used to apply pressure to the bond area while leaving the active area unheated and with no pressure. The bond can be used in either its conductive configuration or insulating configuration. This seal can be used to implement a truly hermetic seal between any two flat surfaces and is R2R compatible. In general, other polymer seals cannot be considered hermetic due to lifetime degradation and high permeability.

Current practice provides that some conventional current systems/methods for bonding/sealing are application specific. For example and for the case of flexible electronics, organic solar cells and organic light emitting diodes, polymer adhesives, swage, or solder is conventionally being used for sealing. The polymer adhesives generally cannot meet the need for oxygen and moisture impermeability of organic solar, light emitting diodes, RIFD tags, liquid crystal displays (LCDs) or electrophoretic displays. Further, even if the initial permeability of the polymer is sufficient, over time the polymer will typically degrade and the leak rate will become too high. Alternative sealing methods are too costly to be implemented in R2R and would make the cost of OPV and OLED too high for lifetime. Also, the use of low temperature solder typically causes the heating of the organic semiconductor past its glass transition temperature and decreases its performance and lifetime.

Another conventional application for integrated circuit technology is solder, which generally has limitations of minimum viable temperature, toxicity, and resolution. Without this bond or hermetic seal, there is generally no alternative means of sealing components that are sensitive to oxygen, moisture and heat. For example, there is no suitable adhesive for organic photovoltaics or organic LEDs, and nothing conventional generally meets the need for impermeability. OLED and OPV lifetime may be extended with the systems/methods of the present disclosure. The implementation of these technologies will be enabled by seals of this disclosure. Further, it is compatible with R2R, and may be made of relatively inexpensive material (for example, silver versus gold in prior conventional technology) so that it reduces cost in applications where gold surfaces are used. The exemplary seal can also take place very quickly and at low temperature to further reduce cost.

Overall, the exemplary seals of the present disclosure improve at least the following: (i) They can create a hermetic seal between any two substantially flat surfaces at room temperature with moderate (e.g., 1-5 MPa) pressure. This allows for the real world implementation of organic semiconductors, RFIDs, LEDs, etc. on plastic substrates, and increases life expectancy of components to useful levels.

(ii) They allow for a decreased cost (ambient, low cost materials, low cost processing), low temperature (room), fast (<5 s) and environmentally benign hermetic seal for glass and metal components (e.g., mobile electronics screens).

(iii) They decrease cost and improve resolution for soldering of IC components through decreased processing steps, low temperature, inexpensive and environmentally benign materials.

(iv) They increase lifetime of devices that work with conventional adhesives but are ultimately lifetime limited by their failure.

The seals/systems/methods of the present disclosure are unique because of their qualities and/or their components. Exemplary qualities include:

(i) mechanically strong, long term stable and impermeable bond (e.g., complete bond with substantially no voids) using metal at room temperature, or below about 150° C., in ambient conditions. The previous art has not been done at room temperature in ambient conditions.

(ii) Forms continuous, or with voids of less than 25 nm, at room temperature. Previous art has had voids on the order of several hundred nm or a discontinuous bond even when heating to 300° C. Exemplary components of the present disclosure include:

(i) Well separated nanorods or metal, metal oxide or alloy. Previous work has used very close-spaced together nanorods or nanoparticles. Prior to the systems and methods of the present disclosure, well separated nanorods could not be made. Some close-spaced rods have been copper, which oxidizes and requires high vacuum processing at over 400° C. to achieve bond quality, therefore it eliminates components with critical temperatures below this. Use of nanoparticles have been those with a capping agent which typically required 160° C. or greater to remove the low diffusivity capping agent and begin the bonding.

(ii) Metallization of plastic can be realized. Previous art has only demonstrated the ability to bond high melting temperature substrates.

In exemplary embodiments, the present disclosure provides for the use of metallic nanorods to bond and seal two substrates. The properties of the resulting bond are mechanical strength comparable to adhesives, impermeability comparable to metals and long term stability comparable to metals. The bond may be attached to any flat substrate and superstrate with strong adhesion. In certain embodiments, the bond is achieved at room temperature with only pressure, or at a temperature above room temperature and less/reduced pressure.

Beginning from the bottom of the structure, generally any substrate or superstrate may be used that has a flatness of less than several hundred nm. These materials may include, but are not limited to: plastics, glass, metal, non-metals. It may be a single piece or part of a long roll and may be in an ambient environment, inert environment or vacuum environment. Onto the substrate, there may be deposited a boundary layer to prevent permeation through the substrate, a conductive layer, an insulating layer or a desiccant layer. On top of this layer, an adhesion layer may be deposited using any suitable mechanism.

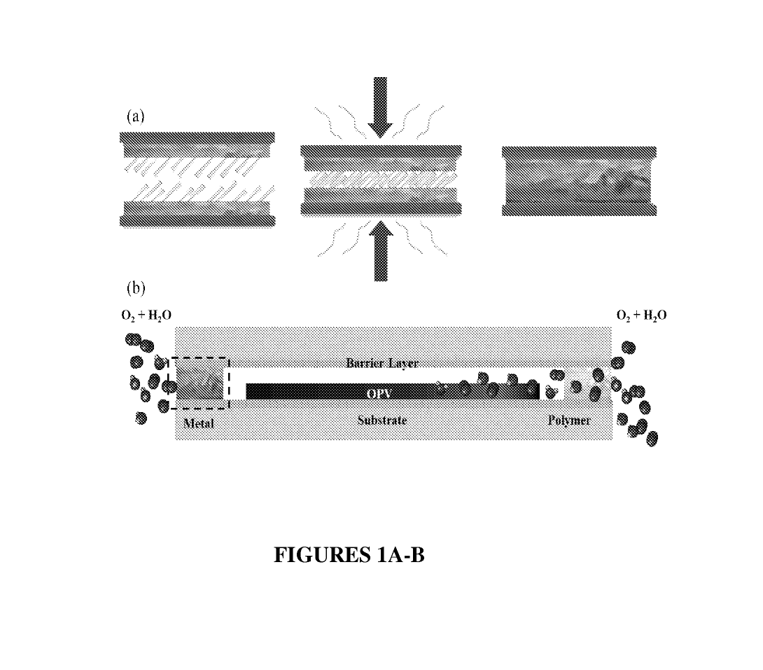

In the case of plastics, glass and silicon, Cr has been used in exemplary embodiments of this disclosure. This layer may be flat or textured. On top of this layer a bond thickness boosting layer of metal or metal alloy may be deposited using either physical or chemical processes. The next layer is then the active bond layer which consists of metal, metal oxide, or alloy nanorods that may be deposited using either physical or chemical deposition. The nanorods should have adequate spacing between one another to allow for the interpenetration of two arrays when vertically aligned over one another—see FIG. 1. The nanorods may be any material—pure metal, alloy, metal oxide or non-metal—that has rapid surface diffusion near room temperature or at a temperature below about 300° C. These materials include, but are not limited to: Au, Ag, Sn, Pb, In, Al, Cu, Sn. Some limiting factors are that there generally cannot be a capping agent or capping layer on top of the rods that limit the fast diffusion or make the disruption of the morphology difficult.

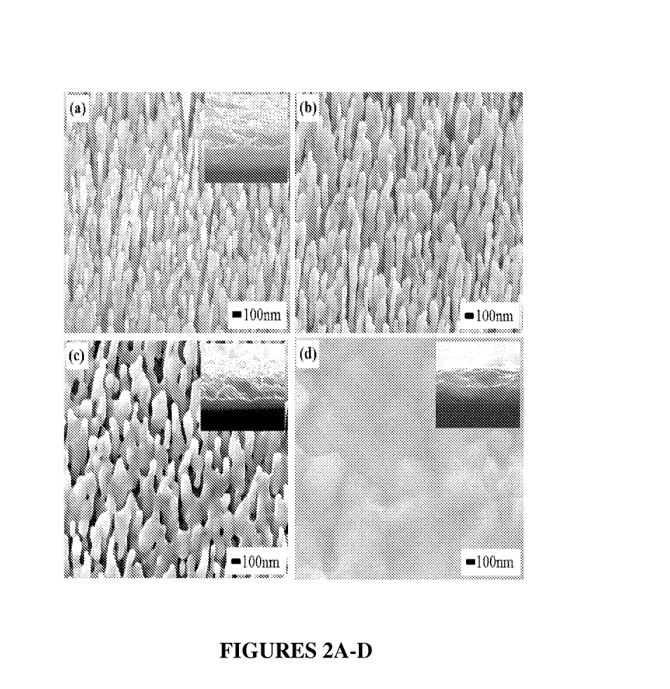

The lack of capping layer results in complete morphological change, from rods to rough film, for Ag at only 100° C. in ambient conditions, see FIG. 2. When compared to capped particles in the literature or Cu rods, which suffer from oxide layers, this diffusion is rapid and complete at low temperatures.

FIG. 1 shows a bond schematic and possible implementation in a solar cell or light emitting diode, for example. The bottom figure (FIG. 1B) is the implementation in an organic solar cell. Top left image of FIG. 1A is a schematic of two adjacent substrates with metal layer and sparse/well separated nanorod array. Middle image of FIG. 1A is when the two layers are pressed together to have inter-penetration, and then heating may or may not be added to get a continuous bond, top right image of FIG. 1A.

FIG. 2 displays a nanorod temperature progression: (a) as fabricated nanorod array with cross section as inset, (b) heated to 50° C. for 1 hr, (c) heated to 75° C. for 1 hr and (d) heated to 100° C. for 5 minutes.

Into the layers of the bond may be deposited any or none of the following: a desiccant layer, an insulating layer, a nanorod seed layer, a layer of surfactant to change the growth mode of the resulting films, any functionalization layer, etc.

The two sides, substrate and superstrate, are then placed to face one another and mechanical pressure and heat, or only mechanical pressure or only heat, is added for some amount of time. In certain embodiments, the temperature has a range from room temperature to about 150° C.

As limits, bonds are achieved with good mechanical strength (e.g., shear stress >10 MPa) at: (i) room temperature with pressures of only about 5 MPa with 5 minutes bonding time (about 400 lbs force over 0.5 in²), (ii) 150° C. with pressure of about 0.7 MPa with 5 minutes bonding time (50 lbs force over 0.5 in²), and (iii) in only 5 seconds using 7 MPa at 150° C.

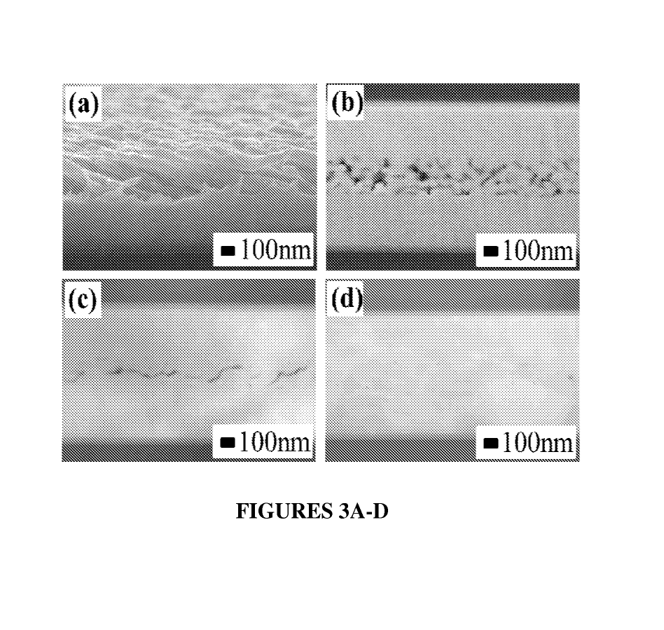

FIG. 3 displays a bond quality demonstration: (a) Cross sectional image of as fabricated nanorods on bond stack structure, (b) FIB (focused ion beam) prepared cross-section of 20 MPa and room temperature for 5 minutes, and (c) FIB cross section of 20 MPa and 75° C. for 1 hr and (d) FIB cross section of 20 MPa and 150° C. for 1 hr.

As noted, FIG. 3 shows the bond quality. FIG. 3A shows the cross-sectional image of the nanorods, underlayer and bond layer on an Si wafer. FIG. 3B shows the bond when only pressure on the order of 20 MPa is used, and FIG. 3C shows the bond under mechanical pressure of 20 MPa and heating to 75° C.

On plastic, the mechanical strength of the bond was tested using pull tests and had a shear strength of about 10 MPa, limited due to delamination from the plastic substrate and the strength of the PET used. It is noted that further mechanical testing may be necessary to determine the upper limit to bond strength; however the current configuration is substantially equal to the strength of cyanoacrylate.

Two copper gaskets for knife edge flanges were bonded together using the systems/methods of the present disclosure, and the leak rate when compared to a single gasket was negligible. Two copper CF gaskets were pressed together with nanorod bonding layers on their mating faces with a pressure of about 20 MPa for about 5 minutes at room temperature. The gasket was placed into a CF flange on a high vacuum chamber. Normal pressure was applied to the flange, as the 8 bolts on a 2.75″ CF were torqued to 12 ft/lbs. When pumped down under full pumping power for 1 hr with a turbo-molecular pump, the vacuum level with a standard KF flange was 6.0×10⁻⁴ Pa. In comparison, the double sealed nanorod gasket also reached to 6.0×10⁻⁴ Pa. After 12 hours, the system reached a base pressure of 2.6×10⁻⁵ Pa, again the two seals, single CF and nanorod bonded CF, were indistinguishable. A polymer seal was used for comparison and had a 1 hour pressure of 9×10⁻⁴ Pa and a 12 hr pump down of 7.5×10⁻⁵ Pa. One difference between the polymer and nanorod seal (which was the baseline) correlated to a minimum leak rate of 1×10⁻⁵ g/ m²/day of air, though the pump is more efficient at higher pressures and the actual leak rate difference is substantially greater than this. This polymer leak rate recorded is too high for use with some organic components, such as OLED and OPV.

It is noted that further investigation may be necessary to characterize the bond/seal quality when created under different parameters (e.g., temperature of the bonding process, duration, vacuum or inert environment, applied pressure, etc.) and the performance of the bond or seal under different environments (including bond strength at different temperatures, calcium leak testing for H₂O, lifetime of bond under elevated temperature, corrosive environment etc.).

The system/method of the present disclosure is particularly advantageous in many areas. For example, it is done with low pressure (1-5 MPa), instead of about 100 MPa. At 1-5 MPa, there is little or no damage to plastic substrates. However, at about 100 MPa causes plastic/permanent deformation of metals, and breaks plastics easily. With added heat, <100° C., the pressure can be further reduced to KPa range.

Moreover, the PVD synthesis of metallic nanorods ensures that the nanostructures are not covered by any shells, which usually are present on nanoparticles from solution processing and can prevent nanostructures from merging seamlessly. Furthermore, PVD synthesis allows for intermediate layers like getter, adhesion layer, insulating layer etc, without disruption to the bond quality and structure.

In the present disclosure, it is shown that with more pressure diffusion is still possible with larger rods and in ambient conditions. The present disclosure also allows for thin, well separated rods to be fabricated and attached to substrates. The exemplary bonding of the present disclosure requires no special systems, manipulation and very basic inexpensive processing. Exemplary cold welding of the present disclosure brings together entire arrays and makes a continuous structure at only about 100° C.

In exemplary embodiments, the systems/methods of the present disclosure are done at either room temperature or slightly elevated temperature in ambient conditions and forms a dense continuous bond and seal. The present disclosure uses surface diffusion of surfaces without a capping layer, so the bonding takes place at very low pressures (e.g., at 150° C. bonding at only 0.7 MPa or less). At room temperature mechanical sealing and strength is achieved at 10 MPa. 100 MPa is probably above the point of plastic deformation for most plastics. The interfacial interactions are significantly stronger and can be optimized or adjusted by adhesion layer engineering.

The present disclosure will be further described with respect to the following examples; however, the scope of the disclosure is not limited thereby. The following examples illustrate, inter alia, the advantageous systems/methods of the present disclosure of low-temperature bonding and sealing with spaced nanorods.

### Example 1

### Metallic Bonding Below about 100° C. through Nanorod Engineering

In general, metallic bonding can be advantageous similar to sealing, but the bonding process has not been possible below about 100° C., above which plastics in solar cells and flexible electronics may degrade. The present disclosure provides, for the first time, for metallic bonding below about 100° C., with excellent sealing and mechanical properties.

The approaches of the present disclosure benefit at least in part from growing small, well-separated metallic nanorods. First, plastic substrates were coated with well-separated Ag nanorods, and the two substrates were pressed together with a pressure of 20 MPa around 75° C. The electron microscopy characterizations revealed dense bonding structures. Further, the leakage tests revealed that the bonding performed better than the plastic environment, and the mechanical tests revealed shear strength of more than 10 MPa, at which the substrate breaks or delaminates from the bond. The leakage resistance, coupled with the low bonding temperature, may advantageously lead to the widespread applications of metallic bonding in organic solar cells and flexible electronics, according to the systems/methods of the present disclosure.

It is noted that previous metallic bonding approaches have not been successful below 100° C. For metallic bonding at low temperatures, sufficient solid diffusion is typically necessary, and fast surface diffusion of nanomaterials has been the focus of multiple attempts. Nanoparticles and nanorods (including longer and slimmer nanowires) can maintain large surface areas when they fit between two substrates. However, either a capping layer or poor separation can render the nanoparticles and nanorods ineffective in the low temperature bonding.

Ag nanoparticles are generally resistant to oxidation, and yet sufficiently inexpensive to use in the electronics industry. In general, the solution processing of Ag nanoparticles leaves an organic capping layer on them, and such layer does not disintegrate below about 160° C. As a result, the Ag nanoparticles will consolidate into a dense film only above this temperature of 160° C. Using a different solution, it is possible to open up the capping layer to allow nanoparticle sintering even at room temperature. The sintered Ag nanorods are in porous form, which may be useful for electrical conduction but the porous structure generally cannot function as seal.

Along a different line, the nanorods from physical vapor depositions generally do not have to face the challenge of an organic capping layer. However, the Cu nanorods that have been attempted are not well-separated, and they coarsen into dense films before bonding. As a result, the bonding temperature of Cu nanorods is typically about 400° C., which is similar to that of Cu thin films. It is noted that the Cu nanorods likely have an untended capping layer of oxide since Cu is prone to oxidation.

It is noted that previous attempts of metallic bonding using nanoparticles and nanorods have not led to a feasible bonding process below 100° C. The present disclosure provides for the generation of well-separated Ag nanoparticles or nanorods (e.g., via the below noted framework for nanorod growth) with no capping layer, with their surfaces not easily oxidized and serving as fast diffusion paths for low temperature bonding.

In exemplary embodiments, the present disclosure identifies a desired temperature of about 75° C. for fast surface diffusion, then uses a hot press to bond two plastic substrates at this temperature; and also to bond two silicon substrates to facilitate imaging after focused ion beam (FIB) milling In characterizing the quality of the bonds, three techniques were employed: scanning electron microscopy (SEM) imaging of cross-section morphology of the bond, leakage rate measurement of a vacuum that is sealed with the bond, and mechanical measurement of shear strength of the bond.

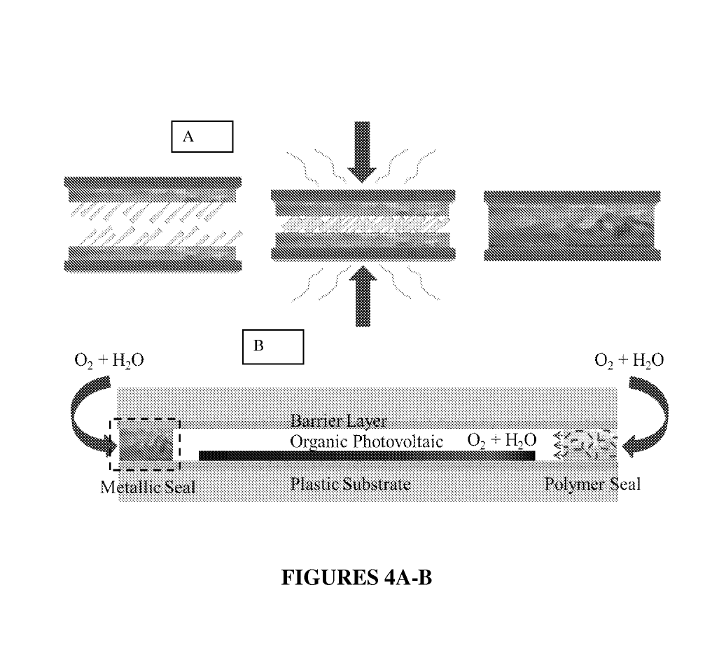

Conceptually, FIG. 4A shows how the exemplary bonding process may work at low temperatures. FIG. 4 depicts schematics of: (a) metallic bonding processes using nanorods, and (b) metallic vs polymer sealing of organic solar cells. As shown in FIG. 4, Ag nanorods cover a plastic substrate with a metallic thin film layer to promote adhesion. As two such substrates are brought together (left image of FIG. 4A), they are under a compressive pressure and then heated (middle image of FIG. 4A).

This hot press leads to a dense metallic bonding (right image of FIG. 4A). Using an example organic solar cell, FIG. 4B illustrates that an exemplary non-degrading metallic bonding can block the leakage of oxygen and moisture into the solar cell (left side of FIG. 4B), and in contrast the leakage of an ordinary plastic sealing that degrades and leaks. As a consequence of the leakage, the solar cell core decomposes.

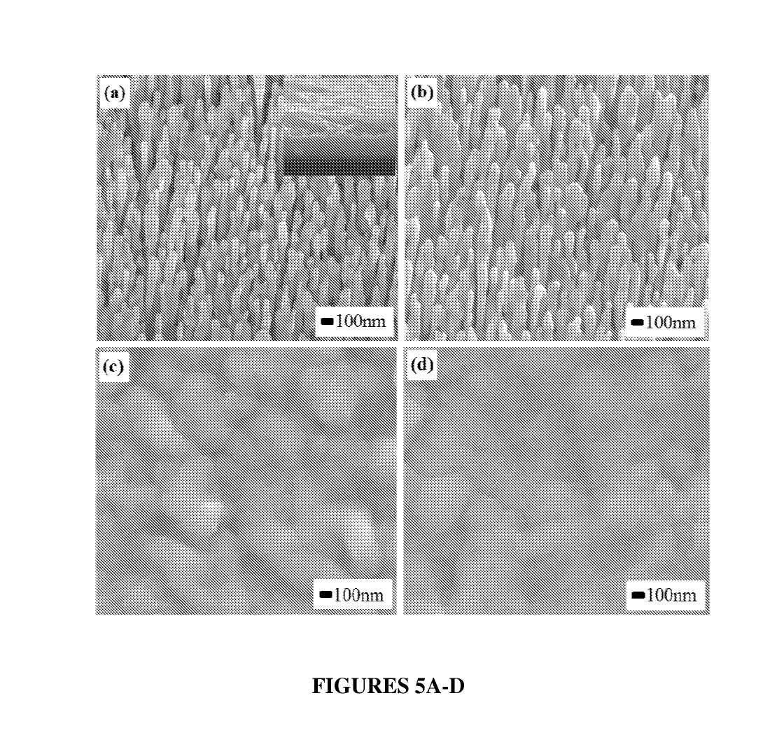

In exemplary embodiments, a temperature for sufficient diffusion is first determined Considering that most bonding processes take about an hour, the Ag nanorods were annealed for about 60 minutes. FIG. 5A shows the as synthesized Ag nanorods, and they coarsen but remain separated after heating at 50° C. for 60 mins (FIG. 5B). FIG. 5 depicts SEM images of

Ag nanorods: (a) before annealing from a tilted top view, with the titled cross-section view as inset, (b) after annealing at 50° C. for 60 mins, (c) after annealing at 75° C. for 60 mins, and (d) after annealing at 100° C. for 60 mins.

However, heating at 75° C. for 60 mins converts the well-separated Ag nanorods into a dense film, as shown in FIG. 5C. Heating at an even higher temperature of 100° C. also leads to the conversion except that the grains of the film are larger than in FIG. 5C. It is noted that the diffusion process is so fast at 75° C. that the conversion of nanorods to film is nearly complete in merely 5 mins, as shown in FIG. 5D. This fast conversion may allow for fast bonding, and this point will be left for future exploration in order to compare and contrast with conventional bonding practices.

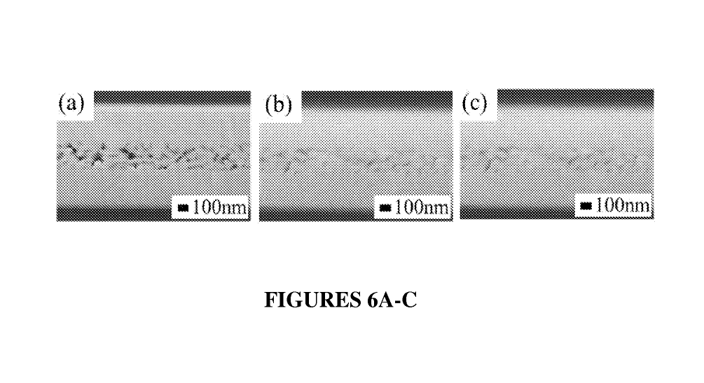

Having identified the desired temperature of diffusion as 75° C. for Ag nanorods, the present disclosure next shows the bonding results around this temperature. FIG. 6A shows that even at room temperature, very brief (e.g., less than one minute) mechanical compression alone leads to well-connected bonding, although some large voids exist. FIG. 6 depicts SEM images of bond cross sections under mechanical compression: (a) at room temperature for less than one minute, (b) at 75° C. for 60 mins, and (3) at room temperature for 60 minutes.

Under this compression, heating at 75° C. for 60 mins leads to a dense bonding (FIG. 6B); the few gaps are about 5 nm in dimension and are much smaller than those from bonding of Cu nanorods at about 400° C. As an exploration, FIG. 6C shows the bond that derives from no heating (e.g., at room temperature) under the same mechanical compression for 60 mins; the improvement over FIG. 6A is noticeable.

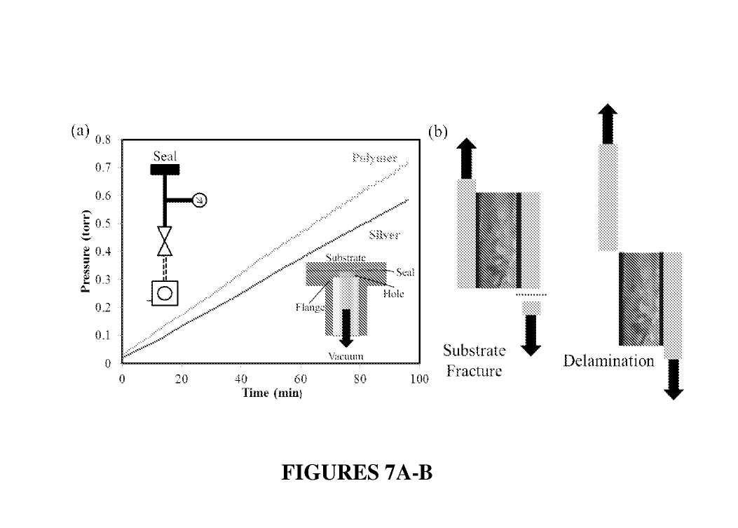

Going beyond the morphologies of the bonds, they were also tested for leakage resistance and mechanical properties. FIG. 7A shows that the pressure in a vacuum increases when the seal is completely plastic, and this rate is reduced when the seal is the metallic bond of FIG. 6B. That is, the Ag bond has better leak resistance than the plastic itself. It is noted that the bonds of FIG. 6A and FIG. 6C can also be similarly tested.

FIG. 7B shows that the bond of FIG. 6B does not break before either the plastic substrate fractures (left image of FIG. 7B) or delamination occurs between the bond and the substrate (right image of FIG. 7B). The shear stress when fracture or delamination happens is 2.1 MPa, indicating that the mechanical strength of the bond is larger than 2.1 MPa. In comparison, the bond from Ag nanoparticles at 160° C. resulted in roughly the same strength.

To put our low temperature metallic bonding in perspective, it was compared and contrasted with other bonding/welding methods based on eutectic or nanoscale melting. Some soft metallic alloys, such as Pb—Sn, have eutectic melting temperature below 100° C. However, the use of Pb is banned or in the process of being banned in developed countries. Even without the concern of Pb toxicity, these bonds are very soft and do not carry much mechanical load. As a result, eutectic melting does not help in the low temperature bonding of organic solar cells or flexible electronics or the like. The nanoscale melting, e.g., the melting of nanomaterials at substantially lower temperature than the bulk melting temperature, has been cited in the literature. However, some experiment and modeling results have shown that nanoscale melting is prominent (or below 50% of the bulk melting temperature) only when the dimension of nanomaterials is below 5 nm or so. At this small dimension, the nanomaterials will become chemically active even if they are Au or Ag. Such chemical reactions may not be completely eliminated even in costly vacuum, which is commonly used in wafer bonding. That is, eutectic melting and nanoscale melting do not enable the low temperature metallic bonding. By contrast, the low temperature bonding of the present disclosure is feasible at low temperatures (e.g., at the low temperature of about 75° C.), and/or in ambient air environment instead of high vacuum.

In summary and in exemplary embodiments, the present disclosure reports the first metallic bonding at about 75° C., in an ambient air environment, by using well-separated Ag nanorods. In certain embodiments, the present disclosure shows that the low-temperature bonding is a result of pronounced surface diffusion of small nanorods. Such characterization shows that the metallic bond is nearly void free, has an air leakage rate superior to polymer adhesives, and has a mechanical strength higher than that of plastics. This low-temperature metallic bonding technology will directly impact the sealing of organic solar cells and flexible electronics or the like.

### Methods—Fabrication of Nanorod Arrays:

Nanorod arrays were fabricated using a high vacuum electron beam physical vapor deposition system. Source materials, 99.95% Cr, Cu, Ag, and Au (Kurt J. Lesker Co.) were placed in the base of the chamber, while sonically cleaned substrates of Si <111>with native oxide, Corning Glass and PET were placed at an angle of about 86.5° relative to the source plane at the top of the chamber.

The throw distance between the source and substrate was roughly 40 cm, and the chamber diameter was 25 cm. The system was closed and pumped down with turbo-molecular pump to a base pressure of 1.0×10⁻⁷ Torr for several hours. Working pressure remained below 5.0×10⁻⁶ Torr. Deposition rates were measured with a quartz crystal microbalance. To achieve the morphologies in exemplary embodiments, Cr adhesion layers were deposited to a thickness of 100 nm at a rate of 0.3 nm/s, Cu was deposited at 1.0 nm/s and Ag was deposited at 1.5 nm/s. Deposition rates were measured perpendicular to incoming flux. Samples were removed from the chamber and immediately characterized or bonded.

Electron beam PVD was used to grow Ag nanorods on Cr-seeded plastic substrates at room temperature, in high vacuum Immediately after coating, two nanorod coated substrates were placed face-to-face, and a pressure was applied at a temperature of 75° C. for 1 hour to form a bond. Bonding was performed in ambient and outside of a clean room. In addition to SEM characterization, the shear strength of the bond was tested and the permeability of the bond was measured by tracking the degradation of a vacuum and leak rate of He gas.

Characterization and annealing:

Immediately after fabrication, samples were moved to a FEI Quanta 250 FEG microscope. Ag samples were annealed using a heating ramp rate of 10° C./min in an alumina tube furnace (MTI Corp.). Imaging was performed immediately after returning to room temperature. X-ray diffraction was done in ambient using a Bruker D-8 Advance system. Annealing of Cu was done in the fabrication chamber without breaking vacuum. An electronically controlled heater conductively heated the sample while the temperature was measured by a thermocouple at the rear of the sample.

Bonding and Bond Analysis:

Bonding was performed immediately after fabrication on a Carver hot press in ambient using. The platens were heated to the desired temperature, ranging from about 23° C., ambient, to 100° C., and 10 mil Teflon was placed as a buffer layer. PET substrates with Cr and Ag were placed facing one another between the platens and pressure was added. Timing began when pressure was applied. Sample cross sections were about 2 cm×2 cm and the applied force was approximately 5 kN. Bonds were held at temperature for times ranging from about 5 seconds to about 60 minutes before pressure was released without allowing for down ramping of temperature.

Bonds for shear testing were configured in lap shear configuration, and unbonded ends were held onto by the grips of an pull testing machine. Strain was controlled at a rate of 0.635 cm/min and load was measured via a calibrated load cell. When the entire lap cross section was used for bonding, the PET failed before the bond. Therefore, the bond area was limited to 0.5 cm×0.5 cm in the middle of the 2 cm×2 cm PET. Bond shear strength was determined by dividing the maximum load before failure by the bond cross sectional area. A total of 10 bonds were tested with average shear strength of 10 MPa.

Bonds were tested for air penetration by testing for low vacuum leak rate. A uniform PET disk was bonded to a PET disk with an about 1 cm hole cut in the interior. This was placed below a rubber gasket in a KF vacuum clamp with a bored through KF flange to provide normal gasket pressure. A Pirani gauge (MKS Industries) and a wide range gauge (Edwards Vacuum) were attached to a vacuum T, with a Edwards RV3 roughing pump to one side and an elbow with the test bond to the other. The area enclosed by vacuum was estimated as 50 cc. The system was pumped down and allowed to remain at a base pressure of 2.0×10⁻² Ton for several minutes.

The wide range and pirani gauge collected data, with an Agilent 34970A data acquisition unit, every 30 seconds and the vacuum degradation was measured for 1.5 hours. The baseline was acquired by using two pieces solid PET with no holes. The only available leak region was at the interface between the PET and the polished vacuum flange, which was treated with corning high vacuum grease. The system had a base leak rate due to the collective air leak of all the components. Only the PET gasket was changed out with the bond sample and the system was returned to vacuum. Bonds were also tested using a high vacuum system and ionization gauge. Two copper gaskets for 2.75″ CF flange were bonded together at room temperature (RT) and under 20 MPa for about 5 minutes. The gaskets were placed in the regular configuration of a single CF gasket and torque down to prescribed torque. The gasket performed substantially identically to a single gasket in pump down for 1 hr and 12 hr. When polymer was used in the same location (metal projects repair adhesive from Liquid Nails® adhesive) the polymer performed substantially worse than the metal seal and single gasket with a minimum additional leak rate greater than MIL standards for hermetic sealing. Razor blade insertion tests were carried out for bonded Si wafers. A razor blade was inserted between the wafers and the wafer failed through cracking without delamination of the remaining bond. It is noted that one can experimentally determine Td, more specifically diffusion, such as by, for example, using change in mean diameter of the nanorods.

Core-shell structure of Cu nanorods coated with Sn:

A new structure was developed to decrease the material cost in this bonding process. The results showed that the exemplary structure, a Cu—Sn core shell nanorod, deforms similarly to Ag under light mechanical pressure and coarsens at a very low temperature (e.g., about 100° C. or less). This is additional evidence of the present disclosure advantageously providing a nanostructure specifically made to facilitate room temperature, low pressure bonding in an ambient environment.

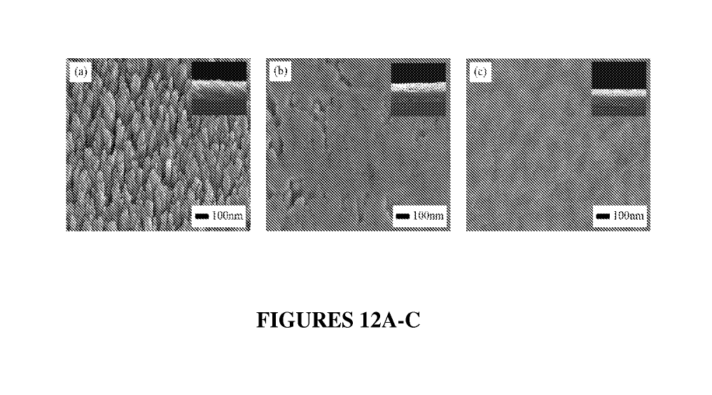

The core-shell structure of Cu nanorods coated with Sn is novel and useful for bonding, and is less expensive than Ag but can perform to the same level as Ag. Some experimental results, as shown in FIGS. 12A-C, indicate that under light mechanical pressure the Cu—Sn core-shell nanorods deform and under low annealing in ambient they coarsen into a continuous film.

More specifically, FIGS. 12A-C show SEM images of: (FIG. 12A) Cu nanorods coated with Sn, (FIG. 12B) Cu—Sn nanorods after mechanical pressure of about 5 MPa, and (FIG. 12C) film from heating Cu—Sn nanorods at about 100° C. under the pressure for about 5 minutes (insets are cross-sectional views).

This is the first time that a well separated nanorod core-shell structure has been realized and that the structure is also useful for the metallic sealing under low pressure, room temperature, in an ambient environment.

For example, in certain applications (e.g., low cost industrial applications) a combination of a nanorod core (e.g., copper or aluminum nanorod core) having a shell material (e.g., a low melting temperature metal shell, such as In, Sn, Zn, etc.) coated at least partially on the nanorod core could be utilized (e.g., to reduce costs).

Such core-shell structures (e.g., a nanorods having a metal nanorod core coated with a metal shell) could provide several advantages, such as, for example, preventing oxidation of the inner/core nanorod, alloying with the inner rod under pressure (e.g., the formation of a bronze phase and a copper phase that is strong), and forming an eutectic alloy.

### Example 2

### Smallest Metallic Nanorods using Physical Vapor Deposition

In general, physical vapor deposition provides a controllable means of growing two-dimensional metallic thin films and one-dimensional metallic nanorods. While theories exist for the growth of metallic thin films, their counterpart for the growth of metallic nanorods has been substantially absent. Because of this absence, the lower limit of the nanorod diameter has been theoretically unknown; consequently the previous experimental pursuit of the smallest nanorods had no clear target. In exemplary embodiments, the present disclosure provides a closed-form theory that defines the diameter of the smallest metallic nanorods using physical vapor deposition. Further, the present disclosure verifies the theory using lattice kinetic Monte Carlo simulations, and validates the theory using experimental data. The present disclosure also carries out a series of experiments to grow well-separated metallic nanorods of about 10 nm in diameter, which are advantageously the smallest ever reported using physical vapor deposition.

The growth of metallic nanorods, which are generally also crystalline, using physical vapor deposition (PVD) allows the control of crystalline structures and chemical composition. Like in the growth of other materials, it is desirable to grow ever smaller nanorods to maximize their nanoscale functionalities. One question is what is the smallest nanorod possible using PVD. In contrast to the growth of crystalline thin films, the growth of metallic nanorods can be dictated by the dynamics of multiple-layer surface steps; this differentiation is not addressed by the existing theories of thin film growth. Consequently, the growth theories of crystalline thin films are generally not applicable to the growth of metallic nanorods. Without a theoretical foundation of nanorod growth, the physical limit of the smallest diameter has been substantially unknown. As a result, the previous pursuit of the smallest nanorods had no clear target, and consequently no clear path to the target.

In the present disclosure, the following is presented: (1) a closed-form theory of the smallest diameter, (2) verification of the theory using lattice kinetic Monte Carlo (LKMC) simulations and validation using experiments, and (3) the realization of the smallest nanorods using theory-guided PVD experiments.

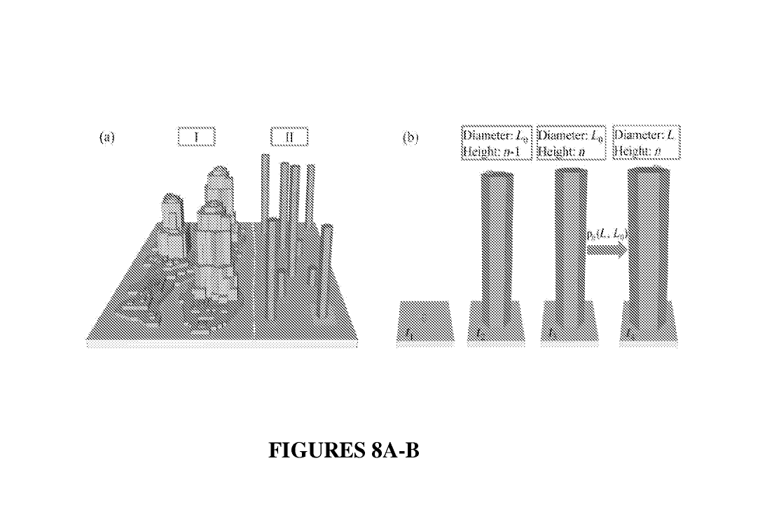

For the theoretical formulation, the conceptual framework of nanorod growth served as a starting point. In contrast to the theories for the growth of large crystals, this framework recognizes that multiple-layer surface steps are kinetically stable; in contrast, the classical theory predicts that such steps are kinetically unstable. Further, these multiple-layer surface steps dictate the diffusion of adatoms during nanorod growth. Under this framework, metallic nanorods generally grow in two modes—I and II (FIG. 8). In mode I, the growth takes place on wetting substrates and nanorods have the general shape of a tower. The competition between multiple-layer and monolayer surface steps typically defines the diameter of nanorods, and also defines the slope on the side of nanorods. The diameter becomes smaller if more of the surface steps are multiple-layer instead of monolayer. In mode II, the growth takes place on non-wetting substrates and nanorods have the general shape of a cylinder (or of an inverted tower if they grow sufficiently tall). Because of the complete, or nearly complete, dominance of multiple-layer surface steps over monolayer surface steps, growth mode II typically results in the smallest diameter of nanorods.

Focusing on growth mode II, the present disclosure first describes an exemplary physical model of nanorod growth; the mathematical formulation then turns the model into a closed-form theory. The model starts with nucleation on a non-wetting substrate [snapshot t₁ in FIG. 8B]. Because of non-wettability, the critical size of nucleating the second layer is about one atomic diameter Aiming at the smallest diameter, the present disclosure considers the complete geometrical shadowing condition—that is, atoms are deposited onto only the top of nanorods, not onto the sides. Once the deposited atoms overcome the large diffusion barrier of multiple-layer steps, they experience much smaller diffusion barriers on the sides and therefore tend to distribute equally along the vertical direction. As a result, they have the shape of a cylinder [snapshot t₂ in FIG. 8B]. Since the diameter of the nanorods is small, only one adatom will be on top most of the time, and a new layer nucleates once two adatoms present simultaneously; this is also called the lone adatom model. The snapshot t₂ in FIG. 8B shows the configuration with the nucleus of a new layer. With the small diameter of nanorods and the large diffusion barrier at the multiple-layer steps or edges of the nanorods, the newly nucleated layer will grow to full coverage before any deposited atoms diffuse to the side. The snapshot t₃ in FIG. 8B shows the configuration when the coverage of one layer is complete. The snapshot t₄ in FIG. 8B is similar to the snapshot t₂, except with one extra layer on top of the nanorod.

Based on the physical model of nanorod growth, the clock in our theoretical formulation starts at the moment when the coverage of the nth layer has just been completed [snapshot t₃ in FIG. 8B ]. The cross-sectional area is A=αL² with L being L₀ at this moment. The α is a geometrical factor: α=π/4 for circular cross sections and α=1 for square cross sections. For easy comparison with experiments, the present disclosure refers to L as the “diameter,” even though it is precisely diameter only for circular cross sections. Before the next layer is nucleated, the adatoms on top diffuse to the sides of nanorods, leading to lateral growth. During this period of lateral growth, mass conservation requires ∫₀^{t}FₑαL²dt=nαL²−nαL₀²; Fₑ is the effective deposition rate on top of the nanorod and t is the time. It should be noted that this conservation equation is valid for mode II of nanorod growth in FIG. 8A, and that it is different from that for the growth of large crystals.

Using the conservation equation and following the lone adatom model, the present disclosure derives the distribution fₙ(L, L₀)=1−exp[(L₀⁵−L⁵)/Lₙ⁵] as the fraction of nanorods on top of which nucleation has taken place when the diameter of the nanorods is L; details of the derivation are available in http://link.aps.org/supplemental/10.1103/PhysRevLett.110.136102. Here, Lₙ=[(10ν_{3D})/nα²Fₑ)]^{1/5} and ν_{3D} is the diffusion jump rate of adatoms over multiple-layer surface steps. The nucleation probability density that the (n+1)th layer starts to nucleate on top of a nanorod of diameter L is then pₙ(L,L₀)=dfₙ(L,L₀)/dL={5L⁴exp[(L₀⁵−L⁵)/L⁵]}/Lₙ⁵.

Next, the present disclosure considers the fact that not all nanorods have the same diameter L₀ at snapshot t₂ in FIG. 8B. Instead, if their size distribution is Sₙ₋₁(L), the size distribution at snapshot t₄ is Sₙ(L)=∫₀^{L}d/Sₙ₋₁(l)pₙ(L,l). For a non-wetting substrate, the present disclosure approximates the size distribution of the first layer as a delta function, S₁(L)=δ(L−0). With this approximation, the present disclosure recursively determines Sₙ(L). Finally, the present disclosure determines the peak diameter Lₘᵢₙ as the L that satisfies dSₙ(L)/dL=0. For a sufficiently narrow size distribution, this peak diameter Lₘᵢₙ represents the smallest diameter. When the number of layers n is large, the present disclosure obtains a closed-form expression:

Lₘᵢₙ≈[(10/α²)×ln(n/2)(ν_{3D}/Fₑ)]^{1/5}.

Since the effective deposition rate Fₑ is proportional to the nominal deposition rate F through Fₑ=F sinΘ with Θ being the incidence angle, Lₘᵢₙ∝(ν_{3D}/F)^{1/5}.

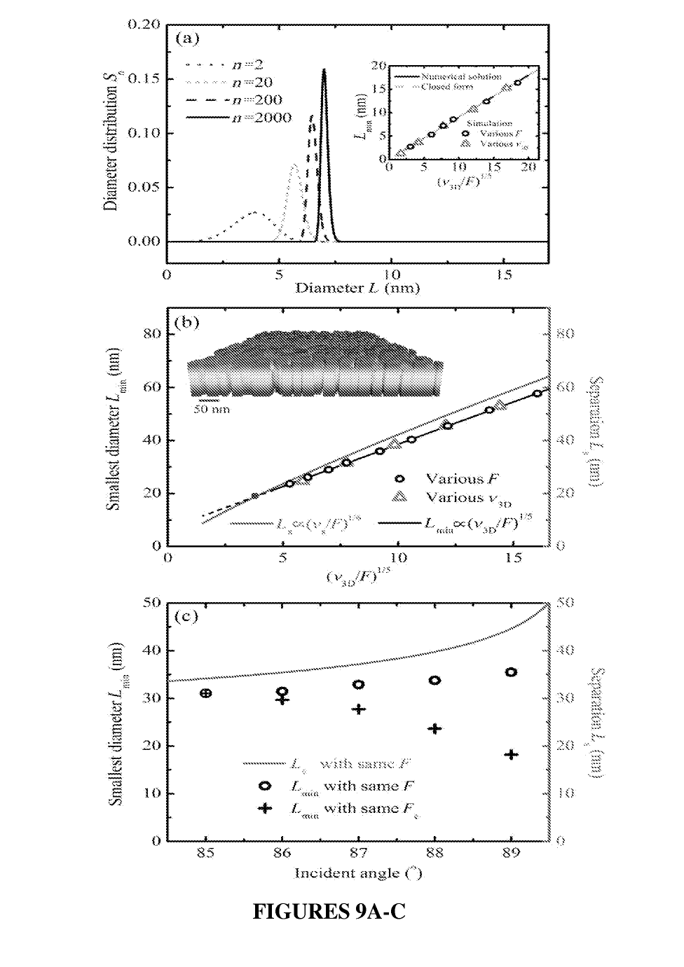

Before using the theory, the present disclosure verifies it here. First, the present disclosure numerically determines Sₙ(L) as a function of the number of layers n (effectively time) (see, e.g., http://link.aps.org/supplemental/10.1103/PhysRevLett.110.136102). As FIG. 9A shows, the peak diameter first increases fast then more slowly with time, and the distribution becomes very narrow as n reaches 2000 layers. The narrow distribution confirms the validity of using the peak diameter as representative of the smallest diameter Lₘᵢₙ.

Further, the numerical solution and the closed-form expression of Lₘᵢₙ are nearly identical as nanorods grow to 2000 layers [FIG. 9A inset]. LKMC simulations using various substrate temperatures or various deposition rates, while keeping other conditions unchanged, show a nearly identical dependence of Lₘᵢₙ on (ν_{3D}/F)^{1/5} as the theory predicts [FIG. 9A inset].

Upon verification of the theoretical formulations, the present disclosure next uses LKMC simulations to test the validity of the theory beyond complete geometrical shadowing conditions. As long as mode II of nanorod growth is operational, the present disclosure still expects the dominance of multiple-layer surface steps, even if geometrical shadowing is incomplete. Indeed, the simulation results [FIG. 9B inset] show the dominance of multiple-layer surface steps. By changing ν_{3D} and F independently, the simulation results show in FIG. 9B that Lₘᵢₙ is still proportional to (ν_{3D}/F)^{1/5} when the incidence angle of atomic flux is about 85°.

Having verified the theory Lₘᵢₙ≈[(10/α²) ln(n/2)×(ν_{3D}/Fₑ)]^{1/5} and extended its applicability as Lₘᵢₙ∝(ν_{3D}/F)^{1/5} under incomplete geometrical shadowing, the present disclosure now uses an experiment to validate it (see, e.g., Stagon et al., Appl. Phys. Lett. 100, 061601 (2012)). In the experiment, Cu nanorods of about 30 nm in diameter grow under a deposition rate of 1 nm/s with an incidence angle of 85°; the substrate temperature is uncontrolled but is within 300 to 350 K. By increasing the deposition rate to 6 nm/s, the growth of nanorods transitions into the growth of a dense film. By including the theoretical separation of nanorod nuclei Lₛ in FIG. 9B, the theory of the present disclosure explains this anomalous transition as the following. The crossover of Lₘᵢₙ and Lₛ occurs at about 20 nm. As deposition rate increases, both Lₘᵢₙ and Lₛ decrease. When they reach about 20 nm, Lₛ becomes smaller than Lₘᵢₙ, so there is no space for separated nanorods to exist. Because of random nucleation, some nanorods are separated at a smaller distance than the theoretical value Lₛ. As a result, nanorods bridge and merge even if Lₛ>Lₘᵢₙ, provided they both are still close to about 20 nm. That is, Lₛ makes it nearly impossible to grow well separated Cu nanorods that are smaller than about 30 nm; beyond the experiments of the present disclosure, others have also reported only nanorods of about 30 nm or larger but not smaller. The fact that the theory explains the anomalous experimental results serves as a validation.

Now that the theory has been verified and validated, the present disclosure uses it to guide the pursuit of the smallest nanorods. The first insight from the theory is that Lₛ is the limiting factor of growing smaller nanorods. By substantially eliminating the constraint of Lₛ, it may become possible to grow smaller and well-separated nanorods of diameter Lₘᵢₙ. It is possible to change Lₛ with minor impact on Lₘᵢₙ by using substrates of different wettability or heterogeneous nucleation, or to change Lₘᵢₙ with minor impact on Lₛ by using different substrate temperatures. Putting this insight into action, the present disclosure applies four strategies: (1) by using large incidence angles, the present disclosure lowers the effective deposition rate to promote the relationship Lₛ>Lₘᵢₙ; (2) by using lower substrate temperatures, the present disclosure takes the advantage of larger activation energy in Lₘᵢₙ to promote the relationship Lₛ>Lₘᵢₙ; (3) by using substrates with heterogeneous nucleation, the present disclosure makes Lₛ ineffective; and (4) by using highly non-wetting substrates, the present disclosure increases Lₛ to promote Lₛ>Lₘᵢₙ. Since the last three strategies are apparent, the present disclosure uses FIG. 9C to show the feasibility of only the first strategy. As the incidence angle becomes larger, while keeping the nominal deposition rate constant, Lₘᵢₙ becomes larger but Lₛ becomes even larger. Indeed, the increase of incidence angle promotes Lₛ>Lₘᵢₙ.

The second insight is that a decrease of ν_{3D} (by an increase of the diffusion barrier of adatoms over multiple layer surface steps) can be effective to reduce the diameter of nanorods according to Lₘᵢₙ∝(ν_{3D}/F)^{1/5}. Putting this insight into action, the present disclosure uses quantum mechanics calculations to identify a metal with a large diffusion barrier of adatoms and therefore small ν_{3D}. The calculations of the present disclosure show that the relevant energy barrier of adatoms diffusion down a multiple-layer surface step in Au is 0.52 eV, much larger than the 0.40 eV in Cu or 0.12 eV in Al; this barrier is in contrast to the Ehrlich-Schwoebel barrier of adatoms diffusion down a monolayer surface step. With this set of data, the second insight suggests that the present disclosure can reach an even smaller diameter for Au nanorods than for Cu nanorods.

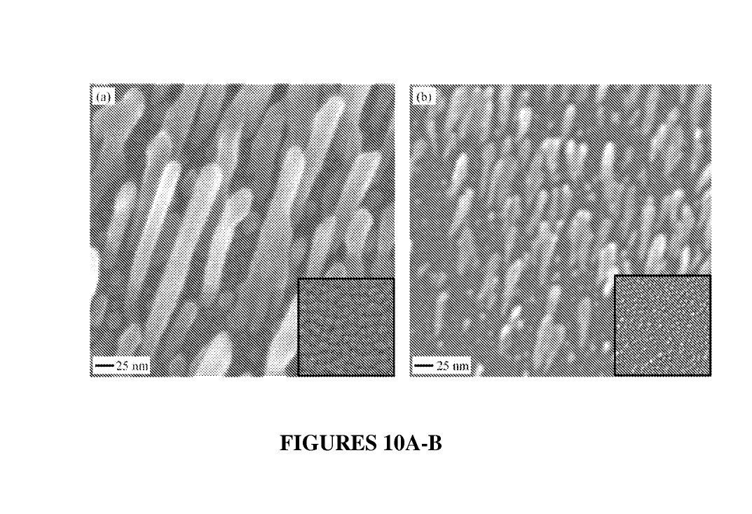

Using the first insight from the theory, the present disclosure designs the growth of Cu nanorods as the following, with additional details available in http://link.aps.org/supplemental/10.1103/PhysRevLett.110.136102. The present disclosure uses a large incidence angle of 88°, a substrate with heterogeneous nucleation sites of SiO₂, and a low substrate temperature of about 250 K; the deposition rate is about 0.1 nm/s. The experiments indeed confirm that well-separated Cu nanorods of about 20 nm in diameter grow [FIG. 10A], as the first theoretical insight suggests. This represents the smallest well-separated Cu nanorods that have ever been reported using PVD. Using both the first and the second insights from the theory, the present disclosure grows Au nanorods using a large incidence angle of 88°, a substrate that is highly non-wetting (e.g., 3M copper conductive tape 1182, 3M Corporation, St. Paul, Minn.), and a low substrate temperature of from about 4 K to about room temperature (substrate temperature can be further dropped also, liquid N₂ or liquid He); the deposition rate is also 0.1 nm/s. The experiments indeed confirm that well-separated Au nanorods of about 10 nm in diameter grow [FIG. 10B], as the two theoretical insights suggest. In fact, some of the Au nanorods are as small as 7 nm in diameter. Once again, the Au nanorods of about 10 nm in diameter are the smallest well-separated metallic nanorods that have ever been reported using PVD. It is noted that the substrate temperature can range from about 4K (liquid helium) to about room temperature. Lowered substrate temperature creates a smaller diameter in some cases.

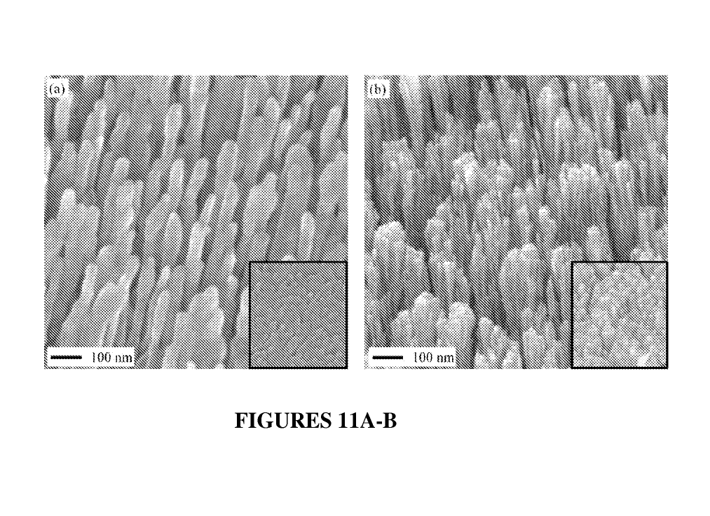

As the well-separated nanorods continue to grow beyond about 800 nm in height, they start to form new architectures. For the case of Cu, bridging occurs but nanorods generally remain separated. In contrast, nearly complete merging of nanorods occurs without the heterogeneous nucleation sites [FIG. 11A inset]. For the case of Au, branching has occurred beyond about 800 nm, but the small diameter and the separation of nanorods both persist. In contrast, a dense columnar Au film grows when the substrate is a regular Si {100} substrate with native oxide [FIG. 11B inset].

In summary and in exemplary embodiments, the present disclosure has formulated a closed-form theory of the smallest diameter of metallic nanorods using PVD, verified the theory using LKMC simulations, and validated it using experiments. Further, using the theory guided PVD experiments, the present disclosure has realized well-separated Cu nanorods of about 20 nm in diameter and well-separated Au nanorods of about 10 nm in diameter. These Au nanorods are advantageously the smallest well-separated metallic nanorods that have ever been reported using PVD.

Although the systems and methods of the present disclosure have been described with reference to exemplary embodiments thereof, the present disclosure is not limited to such exemplary embodiments and/or implementations. Rather, the systems and methods of the present disclosure are susceptible to many implementations and applications, as will be readily apparent to persons skilled in the art from the disclosure hereof. The present disclosure expressly encompasses such modifications, enhancements and/or variations of the disclosed embodiments. Since many changes could be made in the above construction and many widely different embodiments of this disclosure could be made without departing from the scope thereof, it is intended that all matter contained in the drawings and specification shall be interpreted as illustrative and not in a limiting sense. Additional modifications, changes, and substitutions are intended in the foregoing disclosure. Accordingly, it is appropriate that the appended claims be construed broadly and in a manner consistent with the scope of the disclosure.

What is claimed is:

1. A method for bonding or sealing substrates comprising:
a) providing a first substrate and a second substrate;
b) depositing a first array of nanorods on the first substrate;
c) depositing a second array of nanorods on the second substrate;
d) aligning the first substrate over the second substrate, the first and second arrays of nanorods positioned and having adequate spacing between one another to allow for the interpenetration and inter-digitation of the first and second arrays when pressed together; and
e) pressing the first substrate and the second substrate together to interpenetrate, inter-digitate, and bond the first and second arrays of nanorods to one another.

2. The method of claim 1, wherein the first and second substrates are selected from the group consisting of glass, metal, non-metal, silicon, plastic, flexible electronic, organic semiconductor, photovoltaic, LED, resistor, RFID tag, integrated circuit, LCD, solar cell, food or medication vacuum sealing substrates.

3. The method of claim 1, wherein the first and second arrays of nanorods are selected from the group consisting of metallic, non-metallic, alloy, Au, Ag, Sn, Pb, In, Al, Cu, Sn, metal oxide nanorods, and nanorods having a metal core coated with a metal shell.

4. The method of claim 1, wherein the first and second arrays of nanorods are deposited via physical vapor deposition, chemical deposition, physical deposition, or coating.

5. The method of claim 1, wherein the pressing step in step e) occurs at a temperature of 150° C. or less.

6. The method of claim 1, wherein the pressing step in step e) occurs at a temperature of 100° C. or less.

7. The method of claim 1, wherein the pressing step in step e) occurs at a temperature of 75° C. or less.

8. The method of claim 1, wherein the pressing step in step e) occurs at ambient temperature.

9. The method of claim 1, wherein the pressing step in step e) occurs at a pressure from about 1 MPa to about 20 MPa.

10. The method of claim 1, wherein the pressing step in step e) occurs at a pressure from about 1 MPa to about 5 MPa.

11. The method of claim 1, wherein the bond is substantially impermeable to oxygen and moisture.

12. The method of claim 1, wherein the bond has a shear strength greater than about 10 MPa.

13. The method of claim 1, wherein the pressing step in step e) occurs via a heated or unheated die that applies pressure to the first and second substrates.

14. The method of claim 1, wherein each nanorod in the first and second arrays of nanorods is about 20 nm in diameter.

15. The method of claim 1, wherein each nanorod in the first and second arrays of nanorods is about 10 nm in diameter.

16. The method of claim 1, wherein first and second arrays of nanorods are deposited via a high vacuum electron beam physical vapor deposition system.

17. A method for depositing nanorods comprising:
providing source material in a base of a chamber of a physical vapor deposition system;
positioning a substrate in the chamber at an angle of about 85° or greater relative to the base of the chamber; and
depositing the source material onto the substrate via the physical vapor deposition system to form nanorods on the substrate.

18. The method of claim 17, wherein the substrate is at a temperature of from about 4 K to about 24° C. during the deposition of the source material.

19. The method of claim 17, wherein the substrate is at a temperature of about 250 K during the deposition of the source material.

20. The method of claim 17, wherein the substrate includes heterogenous nucleation sites.

21. The method of claim 17, wherein the substrate is a non-wetting substrate.

22. The method of claim 17, wherein the source material is deposited at a rate of from about 0.1 nm/s to about 0.3 nm/s.

23. The method of claim 17, wherein each formed nanorod is about 20 nm in diameter.

24. The method of claim 17, wherein each formed nanorod is about 10 nm in diameter.

25. A sealed substrate comprising:
a first substrate aligned over and bonded to a second substrate, the first and second substrates each having a plurality of nanorods deposited thereon, the plurality of nanorods positioned and having adequate spacing between one another to allow for the interpenetration and inter-digitation of the plurality of nanorods when pressed and bonded together.

26. The sealed substrate of claim 25, wherein the plurality of nanorods include nanorods having a metal core coated with a metal shell.
